(19) United States
(12) Patent Application Publication
(10) Pub. No.: US 2025/0159972 A1
(43) Pub. Date: May 15, 2025

(54) REVERSE-CONDUCTING INSULATED GATE BIPOLAR TRANSISTOR

(71) Applicant: Analog Power Conversion LLC, Bend, OR (US)

(72) Inventors: Dumitru Gheorge SDRULLA, Bend, OR (US); Amaury GENDRON, Bend, OR (US)

(21) Appl. No.: 18/508,770

(22) Filed: Nov. 14, 2023

(51) Int. Cl. H01L 27/06; H01L 29/06; H01L 29/16; H01L 29/20; H01L 29/40; H01L 29/739; H01L 29/861; H01L 29/872

(52) U.S. Cl. CPC H10D 84/617; H10D 8/422; H10D 8/60; H10D 12/441; H10D 62/107; H10D 64/111; H10D 62/8325; H10D 62/8503

(57) ABSTRACT

A semiconductor device comprises a switching device and a cathode pad disposed in a semiconductor die and a termination structure disposed between the switching device and the cathode pad. The switching device comprises a first conduction terminal on a top surface of the semiconductor die, and a second conduction terminal disposed on a bottom surface of the semiconductor die. A drift layer of the semiconductor die may be disposed between the first and second conduction terminals. The cathode pad is disposed on the top surface and electrically connected to the drift layer, and corresponds to a cathode terminal of a diode having the first conduction terminal as an anode terminal. The diode operates as a free-wheeling diode for the switching device when the cathode pad is electrically coupled to the second conduction terminal. Accordingly, the semiconductor device may operate as a Reverse-Conducting Insulated Gate Transistor having reduced snapback.

### BACKGROUND

Transistors may be arranged in a circuit in parallel with a free-wheeling diode (FWD), wherein the transistor conducts current in a first direction when turned on, and the FWD is configured to conduct current in a second direction opposite the first direction when the transistor is turned off.

The FWD may be integrated onto the same die as the transistor. Such integration can provide a number of advantages, including reduced size and lower cost. In addition, the lower thermal resistance that typically results from integrating the FWD into the transistor may increase the output current and power handling capabilities of the device.

However, some techniques known in the art for integrating FWDs into transistors introduce undesirable properties. For example, techniques known in the art for integrating FWDs into Insulated Gate Bipolar Transistors (IGBTs) may cause the IGBT to exhibit snapback.

### SUMMARY OF THE INVENTION

Embodiments relate to semiconductor devices, and in particular to semiconductor devices including vertical transistors having integrated free-wheeling diodes, and to such devices implemented using a wide-bandgap semiconductor such as, for example, Silicon Carbide (SiC) or Gallium Nitride (GaN).

In embodiments, a semiconductor device comprises a switching device, a cathode connection, and a termination structure all disposed in a semiconductor die. The switching device comprises a control terminal, a first conduction terminal disposed on a first surface of the semiconductor die, and a second conduction terminal disposed on a second surface of the semiconductor die, the second surface being opposite the first surface. A drift layer in disposed in the semiconductor die between the first conduction terminal and the second conduction terminal. The cathode connection includes a cathode pad disposed on the first surface of the semiconductor die, the cathode pad being electrically connected to the drift layer, The termination structure is disposed between the switching device and the cathode connection.

In embodiments, the cathode pad operates as a first terminal of a diode and the first conduction terminal operates as a second terminal of the diode.

In embodiments, when the switching device is turned on and a voltage across the first conduction terminal and the second conduction terminal has a first polarity, a first current flows between the first conduction terminal and the second conduction terminal and the diode is reversed biased, and when a voltage across the first conduction terminal and the cathode pad has a second polarity opposite the first polarity, the diode is forward biased.

In embodiments, the diode is a pn-junction diode having an anode corresponding to a well of the switching device and a cathode corresponding to the drift layer, the well having a doping type opposite that of the drift layer.

In embodiments, the diode is a Schottky barrier diode (SBD) having an anode corresponding to a Schottky layer electrically coupled to the first conduction terminal and a cathode corresponding to the drift layer.

In embodiments, the termination structure is a voltage termination structure configured to prevent the propagation of an electric field.

In embodiments, the switching device comprises first and second cells having respective cell control terminals electrically coupled to the control terminal, respective cell first conduction terminals electrically coupled to the first conduction terminal, and respective portions of the drift layer disposed between the respective cell first conduction terminals and the second conduction terminal. The first and second cell include respective anode portions that operate as anodes of the diode. The first cell is closer to the cathode structure than the second cell, and a resistance corresponding to the anode portion of the first cell is higher than a resistance corresponding to the anode portion of the second cell.

In embodiments, the switching device is a vertical Insulated Gate Bipolar Transistor.

In embodiments, the semiconductor die comprises a wide-bandgap semiconductor.

### BRIEF DESCRIPTION OF THE DRAWINGS

FIG. 1A is a schematic of a semiconductor device.

FIG. 1B is a plan view of a semiconductor device according to an embodiment.

FIG. 2A illustrates a semiconductor device according to an embodiment having a first type of termination structure.

FIG. 2B illustrates a semiconductor device according to an embodiment having a second type of termination structure.

FIG. 2C illustrates a semiconductor device according to an embodiment having a third type of termination structure.

FIG. 2D illustrates a semiconductor device according to an embodiment having a fourth type of termination structure.

FIG. 2E illustrates a semiconductor device according to an embodiment having a fifth type of termination structure.

FIG. 2F illustrates a semiconductor device according to an embodiment having a sixth type of termination structure.

FIG. 2G illustrates a semiconductor device according to an embodiment having a seventh type of termination structure.

FIG. 2H illustrates a semiconductor device according to an embodiment having an eighth type of termination structure.

FIG. 3A illustrates a semiconductor device according to an embodiment having a Schottky Barrier Diode (SBD) as the FWD and the first type of termination structure.

FIG. 3B illustrates a semiconductor device according to an embodiment having an SBD as the FWD and the third type of termination structure.

FIG. 3C illustrates a semiconductor device according to an embodiment having an SBD as the FWD and the seventh type of termination structure.

FIG. 4A illustrates a semiconductor device according to an embodiment having tailored contact resistance.

FIG. 4B illustrates a semiconductor device according to another embodiment having tailored contact resistance.

FIG. 5 illustrates a semiconductor device according to an embodiment having an SBD as the FWD and having tailored contact resistance.

FIG. 6A illustrated a structure of a semiconductor device according to an embodiment as a reference for FIG. 6B.

FIG. 6B illustrates current flow during FWD operation of a semiconductor device according to an embodiment.

FIG. 7 illustrates a semiconductor device.

FIG. 8 illustrates snapback such as may occur in the semiconductor device of FIG. 7.

FIG. 9 is a plan view of semiconductor device according to another embodiment.

FIG. 10 illustrates a cross-section of the semiconductor device according to the embodiment of FIG. 9.

### DETAILED DESCRIPTION

Embodiments of the present application relate to electronic devices that integrate a switch with a free-wheeling diode (FWD), and in particular to a Reverse-Conducting Insulated Gate Bipolar Transistor (RC-IGBT) comprising a vertical IGBT and a free-wheeling diode integrated in a semiconductor die, such as a Silicon Carbide (SiC) die.

A detailed description of embodiments is provided below along with accompanying figures. The scope of this disclosure is limited only by the claims and encompasses numerous alternatives, modifications, and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured.

Embodiments are disclosed that have a N-type drift layer (“N-drift”), but embodiments are not limited thereto. A person of ordinary skill in the art would understand that in an embodiment having a P-type drift layer, elements would generally having an opposite doping (where P and N are considered opposites) than shown in the embodiments disclosed herein.

A reverse-conducting transistor refers to a transistor configured to conduct current in a first direction (i.e., from a first conduction terminal to a second conduction terminal) when the transistor is turned on and to conduct current in a second direction (from the second conduction terminal to the first conduction terminal) when the transistor is turned off. Accordingly, a reverse-conducting transistor integrates the function of the transistor with the function of a FWD.

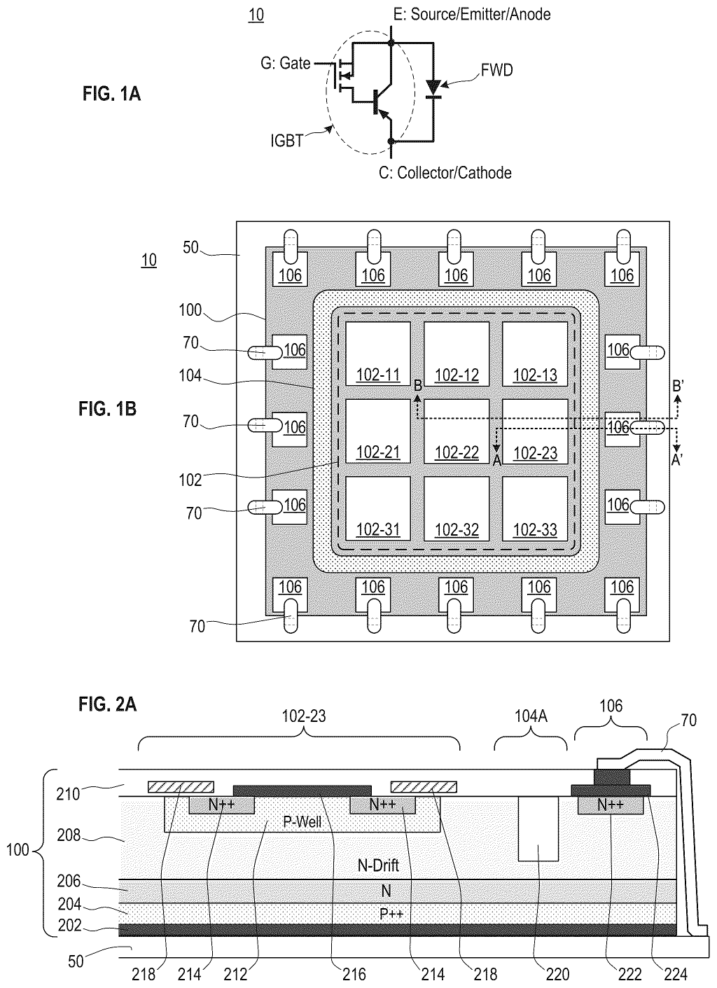

FIG. 1A is a schematic diagram of a reverse-conducting transistor, and specifically of a Reverse-Conducting Insulated Gate Bipolar Transistor (RC-IGBT). The RC-IGBT is represented as including an IGBT and a FWD. The IGBT is represented as a Metal-Oxide-Semiconductor Field Effect Transistor (MOSFET) having a drain coupled to a base of a Bipolar Junction Transistor (BJT).

The RC-IGBT includes a control terminal G couple to a gate of the MOSFET, a first conduction terminal E coupled to a source of the MOSFET, an emitter of the BJT, and an anode of the FWD, and a second conduction terminal C coupled to a collector of the BJT and a cathode of the FWD. The control terminal G, the first conduction terminal E, and the second conduction terminal C may be respectively referred to as the gate terminal G, the emitter terminal E, and the collector terminal C of the RC-IGBT.

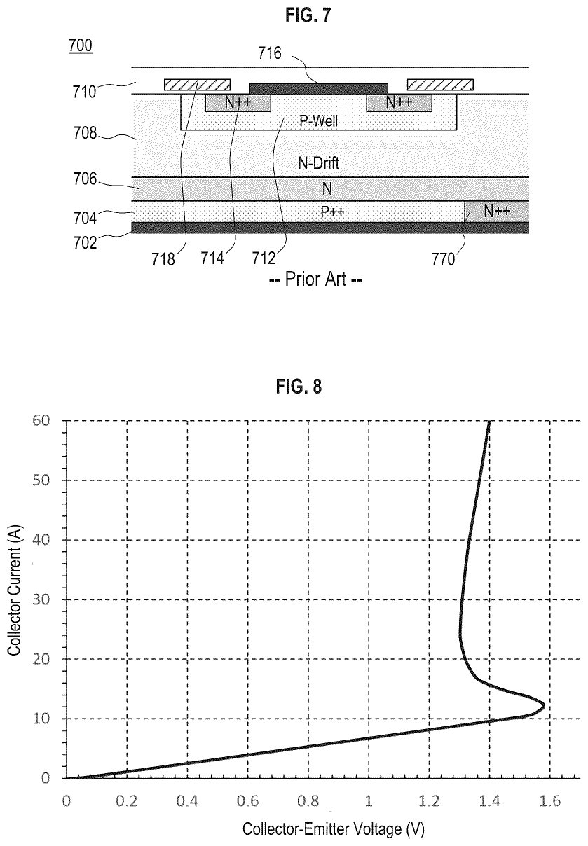

FIG. 7 illustrates a cross-section of an RC-IGBT 700 of the related arts. The RC-IGBT 700 is a vertical RC-IGBT having an emitter electrode 716 and a gate electrode 718 disposed on a top side of a semiconductor substrate and a collector electrode 702 disposed on a bottom side of the semiconductor substrate. The emitter electrode 716, gate electrode 718, and collector electrode 702 may be electrically coupled to an emitter terminal E, a gate terminal G, and a collector terminal C, respectively, of the RC-IGBT.

A collector region 704 of heavily doped P-type semiconductor corresponds to the collector of the BJT of the IGBT and is electrically coupled to the collector electrode 702. A heavily doped N-type semiconductor region 770 formed in the collector region 704 corresponds to a cathode contact of the FWD and is also electrically coupled to the collector electrode 702.

A buffer region 706 of n-doped material is disposed above the collector region 704 and the heavily doped N-type semiconductor region 770, and separates those regions from a drift region 708 of lightly doped N-type semiconductor.

The emitter electrode 716 is electrically connected to a source 714 comprising heavily doped N-type semiconductor and corresponding to a source of the MOSFET of the IGBT. The emitter electrode 716 is also electrically connected to P-well 712 of P-type semiconductor which corresponds to the emitter of the IGBT and the anode of the FWD. The gate electrode 718 is disposed over and separated by a gate dielectric from a region of the P-well 712 corresponding to a channel of the MOSFET; the gate dielectric may be part of insulator layer 710.

The flow of electrons from the N++ region 714 through the channel to an N-drift region 708 is controlled by a gate voltage VG on the gate electrode 718. When a voltage of collector electrode 702 is more positive than a voltage of the emitter electrode 716, the current from the collector electrode 702 to the emitter electrode 716 passes through the collector region 704 (that is, through the BJT of the IGBT) and is controlled by the flow of the electrons through the channel (that is, by the gate voltage VG).

When the voltage of the emitter electrode 716 is more positive than the voltage of the collector electrode 702, the current from the emitter electrode 716 to the collector electrode 702 passes through the heavily doped N-type semiconductor region 770 (that is, through the FWD of the RC-IGBT) and is not controlled by the gate voltage VG.

However, the RC-IGBT 700 of FIG. 7 exhibits a snapback: a sudden drop in the forward collector-emitter voltage of the RC-IGBT. This is due to the N-type semiconductor regions 770 forming a vertical MOSFET in parallel with the IGBT that, during the initial turn-on of the IGBT, allows unipolar conduction to occur until the N-type buffer/P-type collector junction becomes sufficiently forward biased, as reported by E. M. Findlay and F. Udrea in “Reverse-Conducting Insulated Gate Bipolar Transistor: A Review of Current Technologies,” published in IEEE Transactions on Electron Devices, vol. 66, no. 1, pp. 219-231, January 2019, doi: 10.1109/TED.2018.2882687 (hereinafter, Findlay & Udrea).

Specifically, when the RC-IGBT 700 is on, a positive voltage is applied to the collector electrode 702 with respect to the emitter electrode 716, and a current of electrons flows in the vertical MOSFET between the emitter electrode 716 and the heavily doped N-type semiconductor region 770 while the voltage drop across the PN diode junction formed by the collector region 704 and the buffer region 706. As the current increases, the voltage drop across this PN diode junction increases until the collector region 704 begins injection holes into the drift region 708. When enough holes are injected into the drift region 708, a significant reduction in the resistivity of the drift region 708 occurs, which leads to a reduction in the voltage drop across the collector electrode 702 and the emitter electrode 716; that is, the snapback.

Snapback may be particularly strong in SiC IGBTs, relative to silicon IGBTs, because of the higher diode forward turn-on voltage for the PN junction formed by the collector region 704 and the buffer region 706 and the lower resistivity of the drift region 708 in SiC devices.

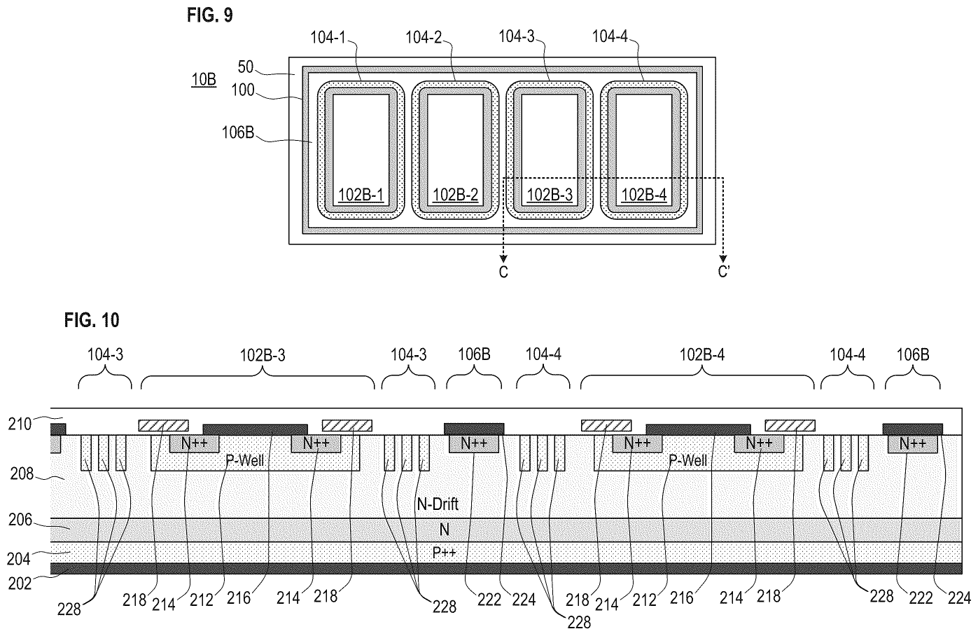

FIG. 8 illustrates the snapback in an RC-IGBT such as shown in FIG. 7, and is based on Findlay & Udrea, FIG. 9. FIG. 8 shows that as the collector current though the RC-IGBT increases up to about 13 A before the BJT of the RC-IGBT turns on, and the collector-emitter voltage increases up to slightly less than 1.6 V. However, as the collector current increases further to 24 A, the collector-emitter voltage “snaps back” to about 1.3 V, after which the collector-emitter voltage increases monotonically with increasing collector current.

The snapback phenomena can cause unequal current distribution among cells of a multi-cell device or among devices connected in parallel, which can lead to uneven heating and instability.

Embodiments of the present invention eliminate the snapback phenomenon by providing FWD functionality via a conduction path toward the top surface of the die, from which electrical conductors will carry the current to the bottom surface of the die. Embodiments include Silicon Carbide (SiC) devices, which have a thin drift layer (relative to devices based on silicon) that is particularly suitable to the implementation of the embodiments.

Specifically, rather than the MOSFET formed in parallel with the IGBT being a vertical MOSFET as in FIG. 7, in embodiments, the MOSFET formed in parallel with the IGBT is a lateral MOSFET with a substantially longer drift region. In embodiments wherein the IGBT is a multi-cell IGBT and the cathode structures are disposed in a periphery of the die, the length of the drift region for the MOSFET is especially long for IGBT cells in the center of the die, so that the MOSFET has negligible effect on IGBT turn on near the center of the die.

In some embodiments, the P-well of the switching transistor (e.g., the IGBT) is used, along with other features of the embodiments, to provide the FWD functionality. In some other embodiments, a Schottky barrier structure is used instead of the P-well.

In some embodiments including a plurality of cells that comprise the switching transistor (each cell operating in parallel to provide the functionality of the switching transistor), respective contact resistances of the cells may be tailored to make the distribution of FWD current among the cells more uniform.

FIG. 1B is a plan view of semiconductor device 10 according to an embodiment. Electrically, the semiconductor device 10 may be represented by the schematic diagram shown in FIG. 1A. The semiconductor device 10 is shown mounted on a conductive substrate 50 which may include an electrically conductive layer covering a top surface thereof.

The semiconductor device 10 comprises a semiconductor substrate 100. The semiconductor substrate 100 may be silicon or may be a wide-bandgap semiconductor such as Silicon Carbide (SiC) or Gallium Nitride (GaN). In embodiments, the semiconductor substrate 100 may be 100 microns or less thick.

The semiconductor device 10 includes a plurality of transistor cells 102-11 through 102-33 disposed in a 3×3 array within a termination structure 104. The plurality of transistor cells 102-11 through 102-33 are connected to each other by conductive structures to form a switching transistor 102, which in the illustrated embodiments is a vertical IGBT. Although FIG. 1B illustrates the switching transistor comprising a plurality of cells arranged in a two-dimensional array, embodiments are not limited thereto, and may include, for example, the switching transistor consisting of a single cell, the switching transistor consisting of a plurality of cell arranged in a one-dimensional array, or another configuration of the switching transistor.

Accordingly, in the illustrated vertical IGBT, gate electrodes disposed on the top surface of the plurality of transistor cells 102-11 through 102-33 are electrically connected by conductive structures (not shown) to provide the gate terminal G shown in FIG. 1A. Emitter electrodes disposed on the top surface of the plurality of transistor cells 102-11 through 102-33 are electrically connected by conductive structures (not shown) to provide the emitter terminal E shown in FIG. 1A. And collector regions of the plurality of transistor cells 102-11 through 102-33, which collector regions are disposed on the bottom surface of the semiconductor substrate 100, are electrically connected by conductive structures (not shown) to provide the collector terminal C shown in FIG. 1A. The collector terminal C may be electrically coupled to the conductive substrate 50. A person of ordinary skill in the art would understand a number of different technologies for providing the above-mentioned conductive structures.

The termination structure 104 is configured to constrain electric fields within the semiconductor substrate 100. The termination structure 104 may be a high-voltage termination structure. A variety of structures known in the art may be used to implement the termination structure 104, and examples thereof will be provided below. The design of the termination structure 104 may be tailored to the desired blocking voltage for the semiconductor device 10.

A plurality of cathode structures 106 are disposed outside of the termination structure 104. Cathode electrodes 70 (wire bonds or the like) electrically couple the plurality of the cathode structures 106 to the conductive substrate 50. In the illustrated embodiment, the cathode electrodes 70 are shown as wire bonds, but embodiments are not limited thereto and may include conductive metal strips or sheets, deposited and patterned conductive layers, and the like.

The plurality of cathode structures 106 are shown in FIG. 1B as being disposed around the edge of the semiconductor substrate 100, which is advantageous for the creation of optimized cathode electrodes 70 for electrically connecting the cathode structures 106 to the conductive substrate 50. However, embodiments are not limited thereto.

The termination structure 104 being between the plurality of cathode structures 106 and the plurality of transistor cells 102-11 through 102-33 prevents the cathode structures 106 from interfering with hole injection into drift regions within the plurality of transistor cells 102-11 through 102-33.

When the switching transistor comprising the plurality of transistor cells 102-11 through 102-33 is turned on and a voltage across the emitter electrodes and collector regions of the plurality of transistor cells 102-11 through 102-33 has a first polarity, current may flow vertically in the semiconductor substrate 100 between the emitter electrodes disposed on the top surface of the plurality of transistor cells 102-11 through 102-33 and the collector regions disposed on the bottom of the plurality of transistor cells 102-11 through 102-33, and between the collector regions and the conductive substrate 50.

In contrast, when the voltage across the emitter electrodes and collector regions of the plurality of transistor cells 102-11 through 102-33 has a second polarity opposite the first polarity, current may flow laterally in the semiconductor substrate 100 between the emitter electrodes of the plurality of transistor cells 102-11 through 102-33 and the plurality of cathode structures 106, and then between the plurality of cathode structures 106 and the conductive substrate 50 through the cathode electrodes 70.

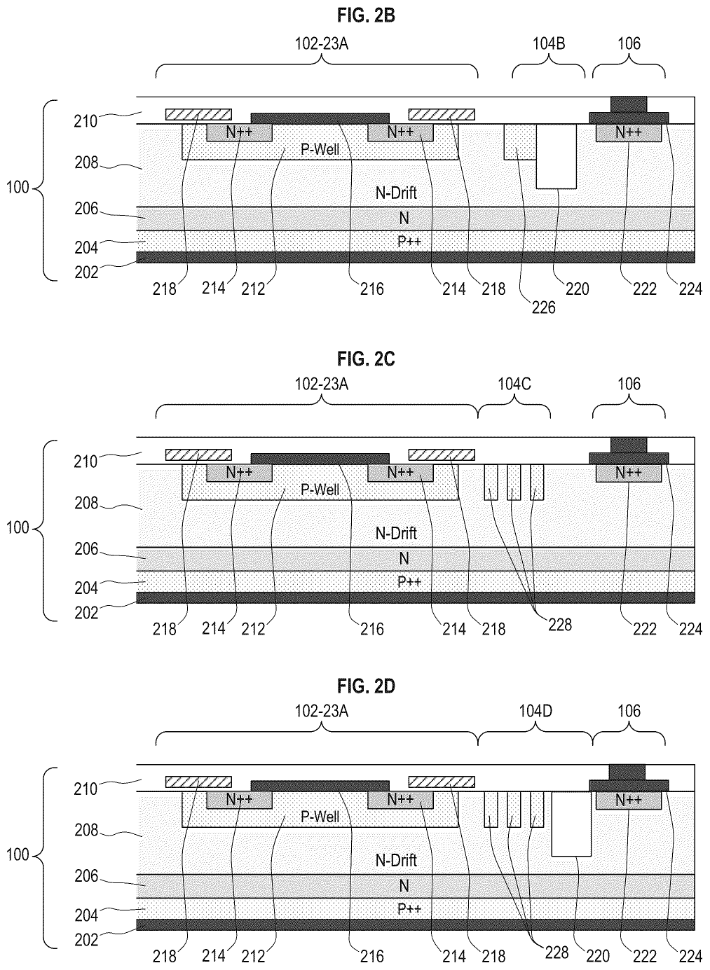

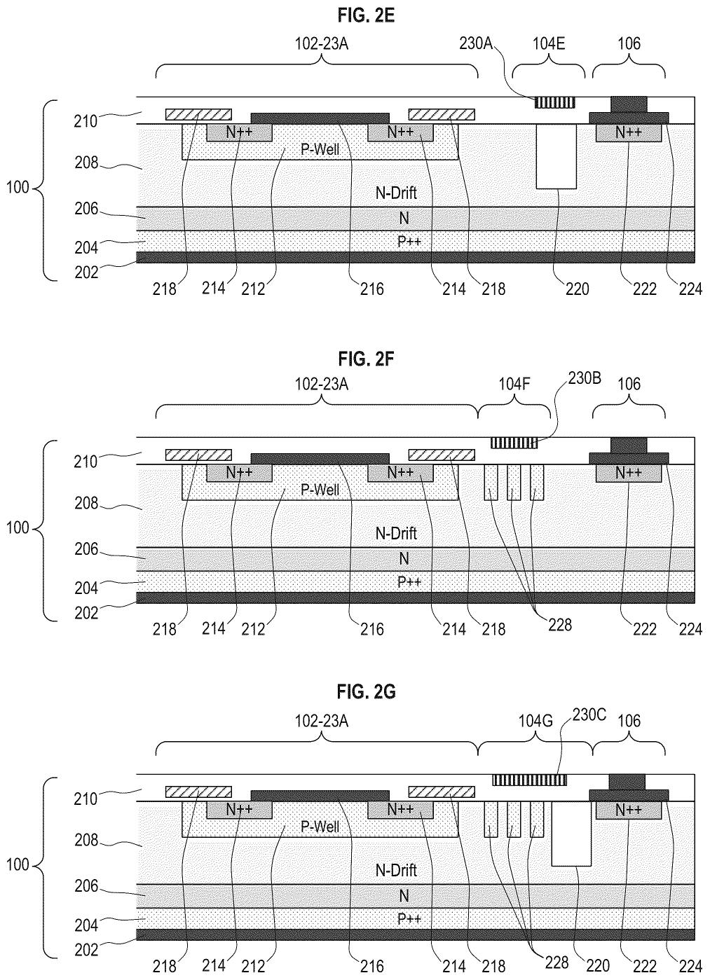

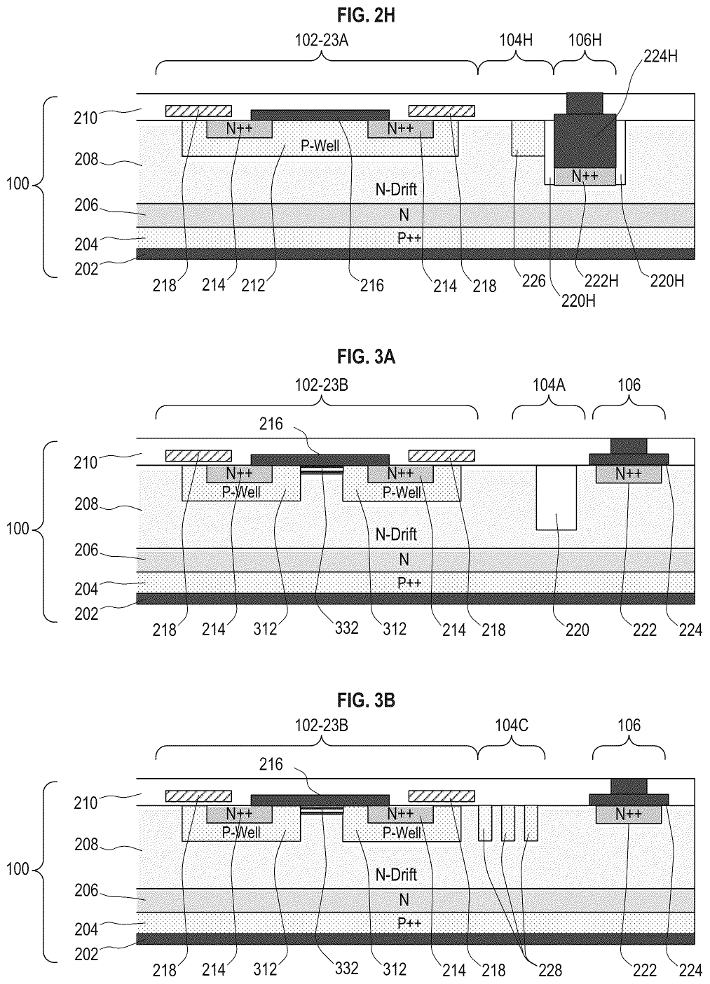

FIGS. 2A through 2H are cross-sections of a portion of semiconductor devices according to respective embodiments. The cross-sections shown may correspond to the line A-A′ in FIG. 1B. Each of FIGS. 2A through 2H illustrates a different implementation of a termination structure corresponding to the termination structure 104 of FIG. 1B, a different implementation of a cathode structure corresponding to the cathode structure 106 of FIG. 1B, or both.

FIG. 2A illustrates a semiconductor device according to an embodiment having a first type of termination structure 104A.

The semiconductor device of FIG. 2A comprises a semiconductor substrate 100 on which a collector electrode 202 of a conductive material (e.g., metal) is formed on a bottom side. Formed above and in contact with the collector electrode 202 in the semiconductor substrate is a collector region 204 comprised of a heavily doped P-type semiconductor. Formed above and in contact with the collector region 204 in the semiconductor substrate is a buffer region 206 of N-type semiconductor. Formed above and in contact with the buffer region 206 in the semiconductor substrate is a drift layer 208 of lightly doped N-type semiconductor.

To form the transistor cell 102-23, a P-well 212 of P-type semiconductor is formed within the drift layer 208. One or more sources 214 are formed of heavily doped N-type semiconductor in the P-well 212, and an emitter electrode 216 comprising conductive material is formed above and in electrical contact with a portion of the P-well 212 and the one or more sources 214. One or more gate electrodes 218 are formed and separated by portions of an insulator 210 over respective regions each comprising contiguous portions of the source 214, the P-well 212, and the drift layer 208.

The transistor cell 102-23 operates as a vertical IGBT as known in the art. Not shown in FIG. 2A are the electrical connections to the gate electrodes 218 and the emitter electrode 216, which may be provided by a variety of means known in the related arts.

A termination structure 104A comprises a trench 220 formed in the drift layer 208 and filled with an insulating material. In embodiments, the trench 220 penetrates the drift layer 208 to a depth greater than or equal to a lowest metallurgical junction between the P-well 212 and the drift layer 208. In embodiments, the trench 220 penetrates between 80 and 90 percent of the thickness of the drift layer 208.

On the other side of the termination structure 104A relative to the transistor cell 102-23 is disposed a cathode structure 106. The cathode structure 106 comprises a cathode contact 222 comprising heavily doped N-type semiconductor disposed in the drift layer 208, and a cathode pad structure 224 disposed on and electrically connected to the cathode contact 222. The cathode pad structure 224 is electrically conductive and is electrically connected to the conductive substrate 50 by the cathode electrode 70.

When the transistor cell 102-23 is turned on and a voltage across the emitter electrode 216 and collector region 202 has a first polarity, current may flow vertically in the drift layer 208 between the emitter electrode 216 and the collector region 202, as occurs in the RC-IGBT 700 of the related arts shown in FIG. 7.

But different from the RC-IGBT 700 of the related arts, when the voltage across the emitter electrode 216 and collector region 202 has a second polarity opposite the first polarity, current may flow laterally in the drift layer 208 between the emitter electrode 216 and the cathode structure 106, and then between the cathode structure 106 and the conductive substrate 50 through the cathode electrode 70.

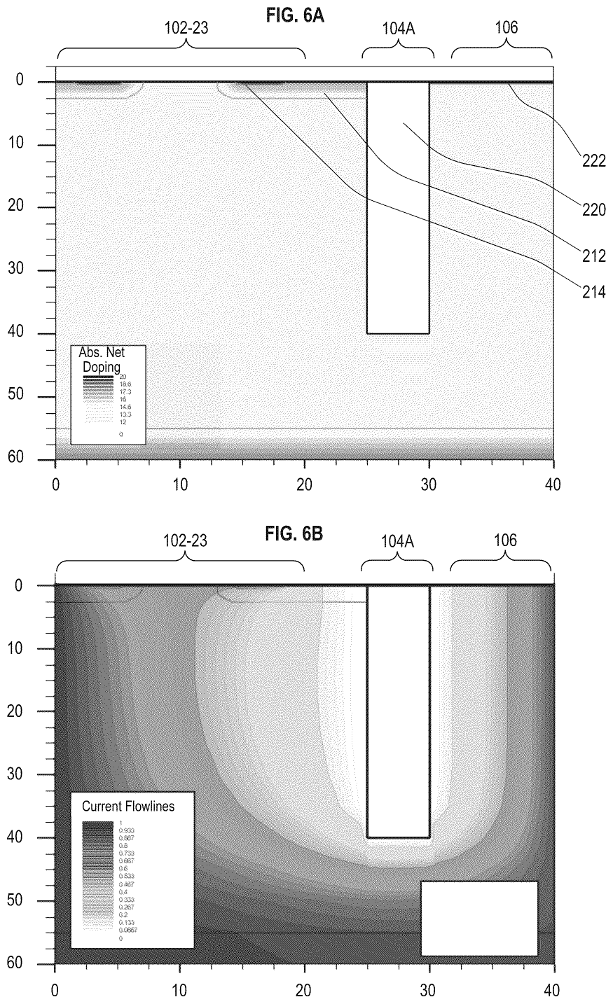

The current flowing laterally in the drift layer 208 between the emitter electrode 216 and the cathode structure 106 flows through portions of the drift layer 208 underneath the trench 220 of the termination structure 104A, as shown in FIG. 6B and discussed below. Accordingly, the series resistance of the FWD may be determined at least in part by the depth to which the trench 220 penetrates the drift layer 208, the thickness of the drift layer 208 beneath the trench 220, or both.

Accordingly, when the voltage across the emitter electrode 216 and collector region 202 has the second polarity, the P-well 212 operates as the anode of the FWD, and the drift layer 208 operates as the cathode of the FWD and is electrically connected to the cathode contact 222. The cathode contact 222 eliminates the need for the N-type semiconductor regions 770 of the RC-IGBT 700 of the related arts shown in FIG. 7. Portions of the drift layer 208 disposed between the P-well 212 and the cathode contact 222 operate as a drift region of the FWD.

FIGS. 2B through 2H illustrate variations on the semiconductor device shown in FIG. 2A. Accordingly, a repetition of the features and operations of the semiconductor device of FIG. 2A that are the same in FIGS. 2B through 2H as in FIG. 2A will be omitted in the interest of brevity.

FIG. 2B illustrates a semiconductor device according to an embodiment having a second type of termination structure. The semiconductor device shown in FIG. 2B differs from the semiconductor device shown in FIG. 2A only in how the termination structure is instantiated.

In FIG. 2B, a termination structure 104B comprises a trench 220 formed in the drift layer 208 and filled with an insulating material, and a floating field ring 226 formed in the drift layer 208 adjacent to the trench 220. The floating field ring 226 may comprise P-type semiconductor.

FIG. 2C illustrates a semiconductor device according to an embodiment having a third type of termination structure. The semiconductor device shown in FIG. 2C differs from the semiconductor device shown in FIG. 2A only in how the termination structure is instantiated.

In FIG. 2C, a termination structure 104C comprises a plurality of floating field rings 228 formed concentrically in the drift layer 208 around transistor cells of the IGBT. The plurality of floating field rings 228 may comprise P-type semiconductor.

FIG. 2D illustrates a semiconductor device according to an embodiment having a fourth type of termination structure. The semiconductor device shown in FIG. 2D differs from the semiconductor device shown in FIG. 2A only in how the termination structure is instantiated.

In FIG. 2D, a termination structure 104D comprises a trench 220 formed in the drift layer 208 and filled with an insulating material, and a plurality of floating field rings 228 formed concentrically in the drift layer 208 between the transistor cell 102-23A and the trench 220. The plurality of floating field rings 228 may comprise P-type semiconductor.

Although FIG. 2D shows the trench 220 on the opposite side of the plurality of floating field rings 228 as the transistor cell 102-23A, embodiment are not limited thereto, and in embodiments, the trench 220 may be disposed between two of the plurality of floating field rings 228 or between the plurality of floating field rings 228 and the transistor cell 102-23A.

Because the termination structure 104D comprises both the plurality of floating field rings 228 and the trench 220, a depth of the trench 220 may be tailored to increase the length of the drift region of the FWD, and by doing this to control the snappiness of the FWD at the expense of higher series resistance of the FWD.

FIG. 2E illustrates a semiconductor device according to an embodiment having a fifth type of termination structure. The semiconductor device shown in FIG. 2E differs from the semiconductor device shown in FIG. 2A only in how the termination structure is instantiated.

The termination structure 104E of FIG. 2E differs from the termination structure 104A of FIG. 2A by including a field plate 230A disposed above the trench 220. The field plate 230A is separated from the drift layer 208 by an insulating material. The field plate 230A may be a floating field plate or may (via an unshown electrical connection) be a “grounded” field plate.

FIG. 2F illustrates a semiconductor device according to an embodiment having a sixth type of termination structure. The semiconductor device shown in FIG. 2F differs from the semiconductor device shown in FIG. 2C only in how the termination structure is instantiated.

The termination structure 104F of FIG. 2F differs from the termination structure 104C of FIG. 2C by including a field plate 230B disposed above the plurality of floating field rings 228. The field plate 230B is separated from the plurality of floating field rings 228 and the drift layer 208 by an insulating material. The field plate 230B may be a floating field plate or may (via an unshown electrical connection) be a “grounded” field plate.

FIG. 2G illustrates a semiconductor device according to an embodiment having a seventh type of termination structure. The semiconductor device shown in FIG. 2G differs from the semiconductor device shown in FIG. 2D only in how the termination structure is instantiated.

The termination structure 104G of FIG. 2G differs from the termination structure 104D of FIG. 2D by including a field plate 230C disposed above plurality of floating field rings 228 and at least a portion of the trench 220. The field plate 230C is separated from the plurality of floating field rings 228 and the drift layer 208 by an insulating material. The field plate 230C may be a floating field plate or may (via an unshown electrical connection) be a “grounded” field plate.

FIG. 2H illustrates a semiconductor device according to an embodiment having an eighth type of termination structure. The semiconductor device of FIG. 2H differs from the embodiments of FIGS. 2A through 2G in having a cathode structure 106H partly integrated into the termination structure.

In the semiconductor device of FIG. 2H, the cathode structure 106H comprises a trench 220H filled with an insulating material and a cathode contact 222H formed at the bottom of the trench 220H and in electrical contact with the drift layer 208. A cathode pad structure 224H comprising a conductive material is disposed within the trench 220H above and in electrical contact with the cathode contact 222H. The cathode pad structure 224H may comprise, for example, a tungsten plug disposed within the trench 220H.

In FIG. 2H the trench 220H is shown disposed on both sides of the anode electrode 224H and the anode contact 222H, but embodiments are not limited thereto. In another embodiment, the insulating-material-filled trench 220H may be disposed only on sides of the cathode pad structure 224H and the cathode contact 222H that are closest to the transistor cell 102-23A.

At least on sides of the cathode pad structure 224H and the cathode contact 222H that are closest to the transistor cell 102-23A, the trench 220H penetrates the drift layer 208 to a depth at least as low as the lowest metallurgical junction between the P-well 212 and the drift layer 208. In embodiments, the trench 220H on the sides of the cathode pad structure 224H and the cathode contact 222H that are closest to the transistor cell 102-23A penetrate between 80 and 90 percent of the thickness of the drift layer 208.

In FIG. 2H, the termination structure 104H comprises at least portions of the trench 220H that are closest to the transistor cell 102-23A. In embodiments, the termination structure 104H may further include any of the other structures shown as comprising the termination structures of FIGS. 2B through 2G, or may include only the trench 220H. For example, the termination structure 104H may further comprises a floating field ring 226 such as shown in FIG. 2B, but embodiments are not limited thereto.

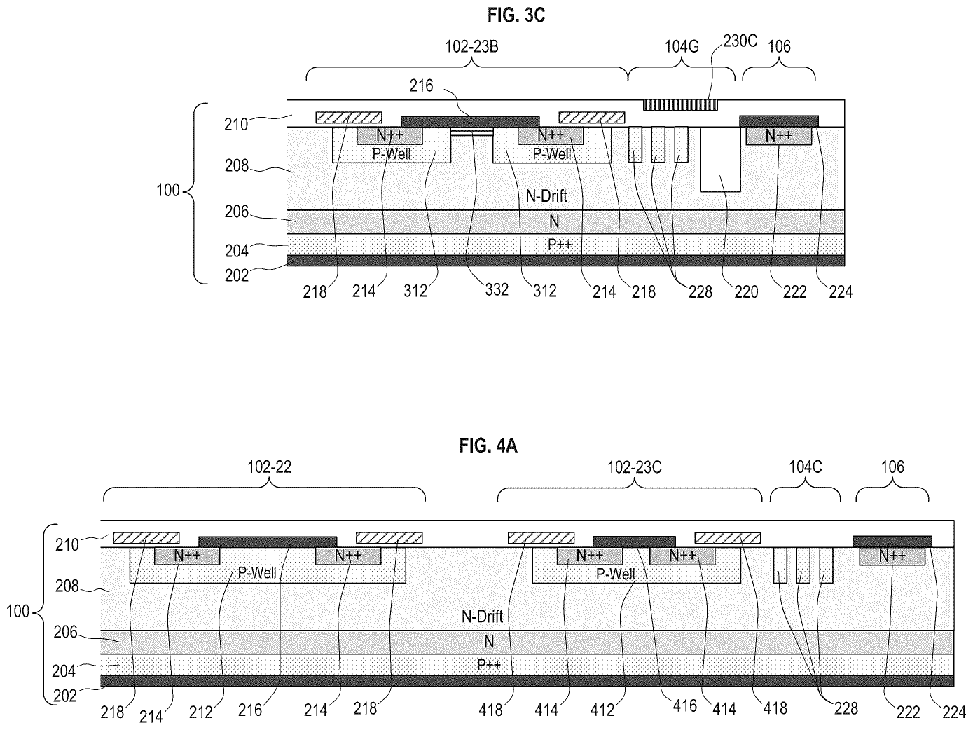

FIGS. 3A through 3C are cross-sections of a portion of semiconductor devices according to respective embodiments. The cross-sections shown may correspond to the line A-A′ in FIG. 1B. Each of FIGS. 3A through 3C illustrate embodiments wherein a Schottky barrier is incorporated into the FWD, each of the figures showing a different a different implementation of a termination structure corresponding to the termination structure 104 of FIG. 1B. While FIGS. 3A through 3C provide fewer examples for the termination structures than FIGS. 2A through 2H, a person of ordinary skill in the art would understand that any termination structure employed in the FIGS. 2A through 2H could be used with the Schottky-barrier-based FWD of FIGS. 3A through 3C.

FIGS. 3A through 3C illustrate variations on the semiconductor device shown in FIGS. 2A, 2C, and 2G, respectively. Accordingly, a repetition of the features and operations of the semiconductor devices of FIGS. 2A, 2C, and 2G that are the same in FIGS. 3A through 3C will be omitted in the interest of brevity.

FIG. 3A illustrates a semiconductor device according to an embodiment having a Schottky Barrier Diode (SBD) as the FWD and the first type of termination structure.

In the embodiment of FIG. 3A, a transistor cell 102-23B comprises a Schottky layer 332 disposed between and in electrical contact with the emitter electrode 216 and the drift layer 208. Here, where the drift layer 208 is an n-type semiconductor, the Schottky layer 332 comprises a material having a higher work function than the drift layer 208, which causes a Schottky barrier to form at the junction of the Schottky layer 332 and the drift layer 208. Accordingly, in the illustrated example, the Schottky layer 332 may comprise titanium (Ti), titanium tungsten (TiW), nickel (Ni), molybdenum (Mo), platinum (Pt), chromium (Cr), tantalum (Ta), or the like.

The Schottky layer 332 is in contact with a portion of the drift layer 208 situated between two portions of the P-well 312, but embodiments are not limited thereto. As a result, when the FWD is conducting current, the current passes between the emitter electrode 216 and the drift layer 208 through the Schottky layer 332, instead of traveling through the P-well 316. That is, the Schottky layer 332 acts as the anode of the Schottky barrier FWD. In contrast, for the embodiment of FIG. 2A, when the FWD is conducting current, the current passes between the emitter electrode 216 and the drift layer 208 through the P-well 212, with the P-well 212 acting as the anode of the PN-type FWD.

FIG. 3B illustrates a semiconductor device according to an embodiment having an SBD as the FWD and the third type of termination structure. As the features and operations of the embodiment of FIG. 3B may be easily understood by a person of skill in the art with reference to the pertinent disclosures of FIGS. 3A and 2C, further description of FIG. 3B is omitted in the interest of brevity.

FIG. 3C illustrates a semiconductor device according to an embodiment having an SBD as the FWD and the seventh type of termination structure. As the features and operations of the embodiment of FIG. 3C may be easily understood by a person of skill in the art with reference to the pertinent disclosures of FIGS. 3A and 2G, further description of FIG. 3B is omitted in the interest of brevity.

In embodiments, any of the variations on the terminations structure shown in FIGS. 2B through 2H may be used with the transistor cell 102-23B of FIGS. 3A through 3C. Furthermore, in embodiments, the merged termination structure and cathode structure shown as termination structure 104H and cathode structure 106H in FIG. 2H may also be used with the transistor cell 102-23B of FIGS. 3A through 3C.

Among the plurality of transistor cells 102-11 through 102-33 of FIG. 1B, if the transistor cells are identical, the transistor cells closest to the cathode structures 106 will conduct most of the current of the FWD, due to the shorter distance through the drift layer 208 and corresponding lower series resistance of transistors cells closer to the cathode structures 106 when operating as an FWD. This may cause hot spots and instability in the device.

To address this problem, embodiments may increase a contact resistance of the transistor cells close to the cathode structures 106 relative to a contact resistance of the transistor cells farther from the cathode structures 106.

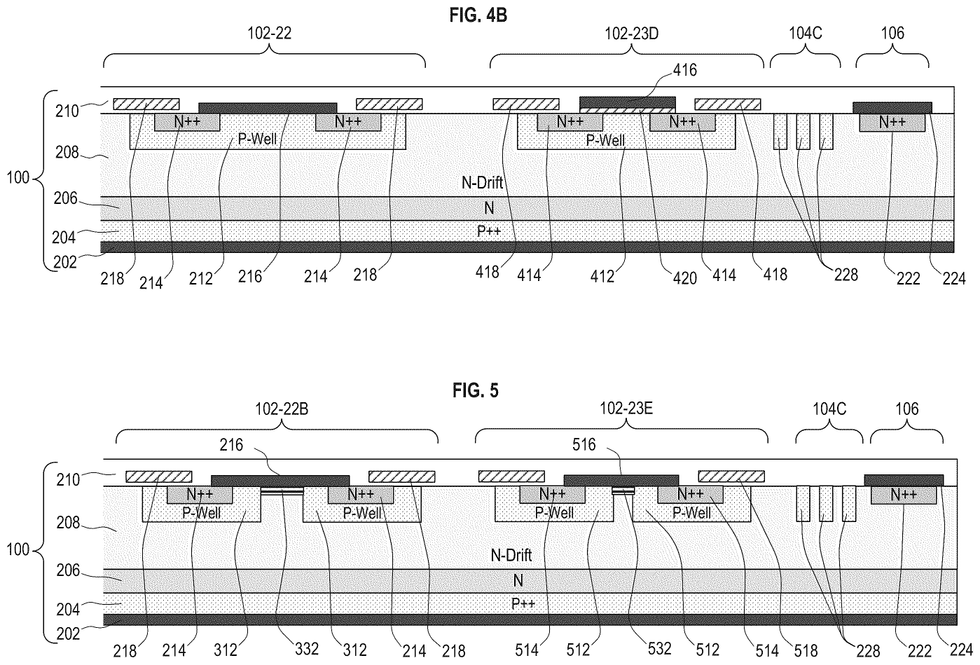

FIGS. 4A, 4B, and 5 are cross-sections of a portion of semiconductor devices according to respective embodiments. The cross-sections shown may correspond to the line B-B′ in FIG. 1B. Each of FIGS. 4A, 4B, and 5 illustrates a different implementation for tailoring respective contact resistance of a plurality of transistor cells such as the of transistor cells 102-11 through 102-33 of FIG. 1B.

FIG. 4A illustrates a semiconductor device according to an embodiment having tailored contact resistance. In FIG. 4A, respective contact resistances of FWD anodes of transistor cells are adjusted by altering an area of a contact window between emitter electrodes and P-wells of transistor cells, a size of the P-wells of the transistor cells, or both.

FIG. 4A illustrates a semiconductor device having a far transistor cell 102-22 and a near transistor cell 102-23C, wherein “near” and “far” refer to the distances of each transistor cell to the nearest cathode structure 106. The far transistor cell 102-22 and near transistor cell 102-23C may respectively correspond to transistor cells 102-22 and 102-23 of FIG. 1B. The semiconductor device further comprises a termination structure 104C and a cathode structure 106.

The far transistor cell 102-22 is shown with a structure corresponding to the transistor cell 102-23 of FIG. 2A, although embodiments are not limited thereto. Accordingly, a detailed description is omitted for the sake of brevity.

The near transistor cell 102-23C comprises a P-well 412, sources 414, an emitter electrode 416, and gate electrodes 418, which are in general terms similar to the corresponding structures in the far transistor cell 102-22.

However, the near transistor cell 102-23C differs from the far transistor cell 102-22 in that the P-well 412 is narrower than the P-well 212, and a contact window between the emitter electrode 416 and the P-well 412 has a smaller area than a contact window between the emitter electrode 216 and the P-well 212. Accordingly, when the two transistor cells are operating as FWDs, an anode resistance of the near transistor cell 102-23C is greater than an anode resistance of the far transistor cell 102-22, which may compensate at least in part for a resistance between the near transistor cell 102-23C and the cathode structure 106 being lower than a resistance between the far transistor cell 102-22 and the cathode structure 106.

FIG. 4B illustrates a semiconductor device according to another embodiment having tailored contact resistance. The semiconductor device of FIG. 4B includes all of the features of the semiconductor device of FIG. 4A, and accordingly a repetition of the description of those features is omitted for brevity.

The semiconductor device of FIG. 4B differs from the semiconductor device of FIG. 4A in that the near transistor cell 102-23D further includes a heavily doped polysilicon layer 420 interposed between the emitter electrode 416 and the P-well 412 and in electrical contact with both. The polysilicon layer 420 increases the resistance between the emitter electrode 416 and the P-well 412, thereby increasing the anode resistance of the near transistor cell 102-23D when the near transistor cell 102-23D is operating as a FWD.

In FIG. 4B, the polysilicon layer 420 is also shown as being interposed between the emitter electrode 416 and the sources 414, but embodiments are not limited thereto, and in embodiments, the emitter electrode 416 may be electrically connected to the sources 414 without using the polysilicon layer 420.

In FIG. 4B, the contact window between the emitter electrode 416 and the P-well 412 is shown as being smaller than a contact window between the emitter electrode 216 and the P-well 212, but embodiments are not limited thereto, and in an embodiment, the physical structures of the far transistor cell 102-22 and the near transistor cell 102-23D may be essentially identical except for the presence of the polysilicon layer 420 in the near transistor cell 102-23D.

FIG. 5 illustrates a semiconductor device according to an embodiment having an SBD as the FWD and tailored contact resistance.

The semiconductor device of FIG. 5 includes the features of the semiconductor device of FIG. 4A, and accordingly a description of the common features is omitted in the interest of brevity. The semiconductor device of FIG. 5 differs from the semiconductor device of FIG. 4A in that the near transistor cell 102-23E and the far transistor cell 102-22B of FIG. 5 respectively include near Schottky layers 532 and far Schottky layers 332.

The far transistor cell 102-22B is shown as essentially identical to transistor cell 102-23B of FIG. 3A, and so a detailed description thereof is omitted for brevity.

The near transistor cell 102-23E comprises a P-well 512, sources 514, an emitter electrode 516, gate electrodes 518, and Schottky layer 532, which are in general terms similar to the corresponding structures in the far transistor cell 102-22B.

The near transistor cell 102-23E differs from the far transistor cell 102-22B in that the area of the Schottky layer 532 is smaller than the area of the Schottky layer 332, and accordingly areas of contact windows between the emitter electrode 516 and the Schottky layer 332 and between the Schottky layer 332 and the drift layer 208 are smaller than the areas of the corresponding contact windows in the far transistor cell 102-22B.

Accordingly, when the two transistor cells are operating as FWDs, an anode resistance of the near transistor cell 102-23E is greater than an anode resistance of the far transistor cell 102-22B, which may compensate at least in part for a resistance between the near transistor cell 102-23E and the cathode structure 106 being lower than a resistance between the far transistor cell 102-22B and the cathode structure 106.

FIG. 6A illustrates a structure of a semiconductor device according to an embodiment as a reference for FIG. 6B. Shown in FIG. 6A are a transistor cell 102-23, a termination structure 104A including a trench 220 filled with an insulating material, a P-well 212, a source 214 formed in the P-well 212, and a cathode structure including a cathode contact 222. FIG. 6A serves as the landscape upon which the characteristics shown in FIG. 6B are displayed.

FIG. 6B illustrates current flow during reverse conduction in an embodiment. As shown in the figure, during reverse conduction (that is, when the device is operating as an FWD) current flows down through the drift layer from the P-wells of the transistor cell 102-23, laterally through the drift layer under the trench of the termination structure 104A, and then up through the drift layer to the cathode contact of the cathode structure 106.

FIG. 9 is a plan view of semiconductor device 10B according to another embodiment. Electrically, the semiconductor device 10B may be represented by the schematic diagram shown in FIG. 1A. The semiconductor device 10B includes elements similar to those shown in the semiconductor device 10 of FIG. 1B (a conductive substrate 50 and a semiconductor substrate 100) and accordingly a repetition of the details thereof is omitted for brevity.

The switching device of the semiconductor device 10B comprises a plurality of cells 102B-1 through 102B-4 that are each similar to the plurality of cells 102-11 through 102-33 of FIG. 1B. The plurality of cells 102B-1 through 102B-4 are shown arranged in a one-dimensional array, but embodiments are not limited thereto.

The semiconductor device 10B differs from the semiconductor device 10 of FIG. 1B in that instead of having a single termination structure 104 disposed around all of the plurality of cells, the semiconductor device 10B includes a plurality of termination structures 104-1 to 104-4 that are respectively disposed around the plurality of cells 102B-1 through 102B-4.

Furthermore, a cathode structure 106B is disposed between each pair of the plurality of cells 102B-1 through 102B-4 as well as around the plurality of cells 102B-1 through 102B-4. Like the cathode structures 106 of FIG. 1B, the cathode structure 106B is electrically coupled to the conductive substrate 50 (for example, by one or more wire bonds, metal strips, or metal sheets) but these connections are omitted from FIG. 9 for clarity.

FIG. 10 illustrates a cross-section along the line C-C′ of the semiconductor device 10B according to the embodiment of FIG. 9. Referring to FIG. 2C, like-numbered elements in FIG. 10 refer to similar elements as those shone in FIG. 2C, and accordingly a repetition of the details thereof is omitted for brevity.

As shown in FIG. 10, termination structures 104-3 and 104-4 surround the cells 102B-3 and 102B-4, respectively, and portions of the cathode structure 106B are disposed around and between the termination structures 104-3 and 104-4. Accordingly, current paths between each of the plurality of cells 102B-1 through 102B-4 and the cathode structure 106B are substantially similar to each other.

The termination structures 104-3 and 104-4 shown in FIG. 10 correspond to the termination structure 104C of FIG. 2C, but embodiments are not limited thereto, and for example may include any of the termination structures 104A through 104H shown in FIGS. 2A through 2H.

Illustrative embodiments have been provided wherein a Reverse-Conducting Insulated Gate Bipolar Transistor (RC-IGBT) having reduced snapback may be formed by disposing one or more cathode structures of a free-wheeling diode on a same surface as emitters and gates of one or more transistor cells of the IGBT, and disposing one or more termination structures between the cells and the cathode structures to prevent the cathode structures from interfering with hole injection into a drift layer of the IGBT.

Furthermore, when the IGBT comprises a plurality of transistor cells, anode-related resistances of each of one or more of the plurality of transistor cells may be respectively adjusted according to a distance or a resistance between that cell and the cathode structures in order to equalize current flowing through each cell when the cells are operating as the FWD.

Embodiments allow a device such as SiC IGBTs to benefit from the integration of a FWD into the device without suffering some of the drawbacks that may arise when such integration is performed using technologies known in the arts. A RC-IGBT with one or more cathode structures of the FWD placed on the top side of the die eliminates the snapback found in RC-IGBTs known in the arts.

The integrated FWD included in the RC-IGBT can be a P-N diode formed between the P-well and the N-drift layer, or can be a Schottky barrier diode integrated in the entire active area of the device or in specific regions.

The cathode structure of the FWD disposed on the top of the device must be connected to the backside of the die. The connection may be made during assembly, either by, for example, wire-bonding or by soldering sheets of copper (Cu) based electrodes. By using sheets of Cu based electrodes, additional front side cooling may be provided, and the stray inductance of the connection between the top-side anodes and the backside may be brought almost to zero.

Trenches in the termination structure or outside of it can control the length of the drift region of the FWD, and therefore its snappiness is improved, at the expense of a higher forward voltage through the FWD.

To improve the current density distribution across the die, and therefore improve the temperature distribution across the device, the contact resistance of FWD anodes of cells of the IGBT may be tailored so that a contact resistance of the cells is higher for cells closer to the top-side cathodes structures, e.g., cells closer to the edge of the die. Tailoring the contact resistance may be performed by narrowing of P-wells of cells that are closer to the top-side anodes, interposing a polysilicon layer into a conduction path between emitter electrodes and P-wells of cells that are closer to the top-side anodes, or both. When the FWD comprises a Schottky barrier diode formed in a JFET region of a cell of the IGBT, narrowing the JFET regions of cells that are closer to the top-side anodes may both increase the contact resistance at the Schottky barrier and increase the resistance of the JFET “neck.” In addition, these techniques may be combined.

Aspects of the present disclosure have been described in conjunction with the specific embodiments that are presented as illustrative examples, but embodiments are not limited to those shown in the drawings or those mentioned in the accompanying text. Numerous alternatives, modifications, and variations to the disclosed embodiments may be made without departing from the scope of the claims set forth below. Embodiments disclosed herein are not intended to be limiting.

What is claimed is:

1. A semiconductor device comprising:
a switching device comprising:
a control terminal,
a first conduction terminal disposed on a first surface of a semiconductor die,
a second conduction terminal disposed on a second surface of the semiconductor die, the second surface being opposite the first surface, and
a drift layer disposed in the semiconductor die the between the first conduction terminal and the second conduction terminal;
a cathode structure disposed in the semiconductor die and having a cathode pad disposed on the first surface of the semiconductor die, wherein the cathode pad is electrically connected to the drift layer, and
a termination structure disposed between the switching device and the cathode structure.

2. The semiconductor device of claim 1, wherein the cathode structure comprises a cathode contact disposed in contact with the drift layer and electrically coupled to the cathode pad.

3. The semiconductor device of claim 2, wherein the cathode contact is disposed at the bottom of a trench formed in the drift layer.

4. The semiconductor device of claim 1, where the termination structure is a voltage termination structure configured to prevent the propagation of an electric field.

5. The semiconductor device of claim 4, where the termination structure comprises an insulator-filled trench that penetrates between 80 and 90 percent of the drift layer.

6. The semiconductor device of claim 4, where the termination structure comprises a floating field ring disposed in the drift layer.

7. The semiconductor device of claim 4, where the termination structure comprises a field ring plate disposed above the drift layer and an insulating material disposed between the field plate and the drift layer.

8. The semiconductor device of claim 1, wherein the cathode pad operates as a first terminal of a diode and the first conduction terminal operates as a second terminal of the diode.

9. The semiconductor device of claim 8,
wherein when the switching device is turned on and a voltage across the first conduction terminal and the second conduction terminal has a first polarity, a first current flows between the first conduction terminal and the second conduction terminal and the diode is reversed biased, and
wherein when a voltage across the first conduction terminal and the cathode pad has a second polarity opposite the first polarity, the diode is forward biased.

10. The semiconductor device of claim 8, wherein the diode is a pn-junction diode having an anode corresponding to a well of the switching device and a cathode corresponding to the drift layer, the well having a doping type opposite that of the drift layer.

11. The semiconductor device of claim 8, wherein the diode is a Schottky barrier diode (SBD) having an anode corresponding to a Schottky layer electrically coupled to the first conduction terminal and a cathode corresponding to the drift layer.

12. The semiconductor device of claim 8,
wherein the switching device comprises first and second cells having respective cell control terminals electrically coupled to the control terminal, respective cell first conduction terminals electrically coupled to the first conduction terminal, and respective portions of the drift layer disposed between the respective cell first conduction terminals and the second conduction terminal,
wherein the first and second cell include respective anode portions that operate as anodes of the diode,
wherein the first cell is closer to the cathode structure than the second cell, and
wherein a resistance corresponding to the anode portion of the first cell is higher than a resistance corresponding to the anode portion of the second cell.

13. The semiconductor device of claim 12,
wherein the anode portions of the first and second cells correspond to respective wells of the first and second cells, the wells having a doping type opposite that of the drift layer, and
wherein a contact area of the well of the first cell to the cell first conduction terminal of the first cell is smaller than a contact area of the well of the second cell to the cell first conduction terminal of the second cell.

14. The semiconductor device of claim 12,
wherein the anode portions of the first and second cells correspond to respective wells of the first and second cells, the wells having a doping type opposite that of the drift layer, and
wherein a contact area of the well of the first cell to the drift layer is smaller than a contact area of the well of the second cell to drift layer.

15. The semiconductor device of claim 12,
wherein the anode portions of the first and second cells correspond to respective Schottky layers of the first and second cells, and
wherein a contact area of the Schottky layer of the first cell to the cell first conduction terminal of the first cell is smaller than a contact area of the Schottky layer of the second cell to the cell first conduction terminal of the second cell.

16. The semiconductor device of claim 12,
wherein the anode portions of the first and second cells correspond to respective Schottky layers of the first and second cells, and
wherein a contact area of the Schottky layer of the first cell to the drift layer is smaller than a contact area of the Schottky layer of the second cell to the drift layer.

17. The semiconductor device of claim 12,
wherein the first cell includes a first polysilicon layer having a first thickness disposed between the anode portion of the first cell and the cell first conduction terminal of the first cell, and
wherein the second cell includes a second polysilicon layer having a second thickness smaller than the first thickness disposed between the anode portion of the second cell and the cell first conduction terminal of the second cell, or does not include a polysilicon layer disposed between the anode portion of the second cell and the cell first conduction terminal of the second cell.

18. The semiconductor device of claim 8,
wherein the switching device comprises first and second cells having respective cell control terminals electrically coupled to the control terminal, respective cell first conduction terminals electrically coupled to the first conduction terminal, and respective portions of the drift layer disposed between the respective cell first conduction terminals and the second conduction terminal,
wherein the first and second cell include respective anode portions that operate as anodes of the diode,
wherein the termination structure comprises a first termination structure disposed around the first cell and a second termination structure disposed around the second cell, and
wherein the cathode structure is disposed around and between the first termination structure and the second termination structure.

19. The semiconductor device of claim 1, wherein the switching device is a vertical Insulated Gate Bipolar Transistor.

20. The semiconductor device of claim 1, wherein the semiconductor die comprises a wide-bandgap semiconductor.
